(19) United States
(12) Patent Application Publication
(10) Pub. No.: US 2014/0230868 A1
(43) Pub. Date: Aug. 21, 2014

(54) GRAPHENE-CONTAINING COMPOSITE LAMINATE, THERMOELECTRIC MATERIAL, AND THERMOELECTRIC DEVICE INCLUDING THE THERMOELECTRIC MATERIAL

(71) Applicant: Samsung Electronics Co., Ltd., Suwon-Si (KR)

(72) Inventors: Chong-joon RYU, Seoul (KR); Seung-hyun HONG, Seoul (KR); Won-young KIM, Seoul (KR); Seung-hyun BAIK, Seoul (KR); Sang-hoon LEE, Seoul (KR); Jae-young CHOI, Suwon-si (KR)

(21) Appl. No.: 13/930,563

(22) Filed: Jun. 28, 2013

(30) Foreign Application Priority Data
Feb. 19, 2013 (KR) 10-2013-0017653

(51) Int. Cl. H01L 35/22

(52) U.S. Cl. CPC H01L 35/22
USPC 136/200

(57) ABSTRACT

A composite laminate may include graphene and a thermoelectric inorganic material including a single crystal having a hexagonal crystal system.

### CROSS-REFERENCE TO RELATED APPLICATIONS

This application claims the benefit of Korean Patent Application No. 10-2013-0017653, filed on Feb. 19, 2013, in the Korean Intellectual Property Office, the disclosure of which is incorporated herein in its entirety by reference.

### BACKGROUND

1. Field

Example embodiments relate to graphene-containing composite laminates, thermoelectric materials, and thermoelectric devices including the thermoelectric materials.

2. Description of the Related Art

A thermoelectric phenomenon denotes a reversible and direct energy conversion between heat and electricity in which the flow of current or a voltage is generated due to the diffusion movement of electrons or holes that is caused by a temperature gradient generated in a material. The thermoelectric phenomenon may be classified into the Peltier effect, which is applied to the cooling field by using a temperature difference between both ends of a material formed by an applied current and the Seebeck effect, which is applied to the power generation field by using an electromotive force generated from the temperature difference between both ends of a material.

The thermoelectric material has been used in semiconductor apparatuses having a heating problem that is difficult to be resolved by passive cooling systems and active cooling systems for an electronic device. Also, demand is growing in cooling application areas in which heat problems may not be resolved by a typical cooling system using a refrigerant gas compression method. Thermoelectric cooling is a vibration-free and low-noise environmentally-friendly cooling technique which does not use a refrigerant gas causing environmental issues, and when a thermoelectric cooling efficiency is improved by the development of a high-efficiency thermoelectric cooling material, an application thereof may be further expanded to general-purpose cooling areas, e.g., refrigerators and air conditioners.

Also, when a thermoelectric power generation material is used in heat-dissipating portions in automobile engines and industrial plants, power may be generated by the temperature difference between both ends of a material, and thus, the thermoelectric power generation material has received attention as a renewable energy source.

### SUMMARY

Example embodiments provide composite laminates containing graphene and a thermoelectric inorganic material, which have an improved thermoelectric conversion efficiency or methods of preparing the same.

Example embodiments provide thermoelectric materials including the composite laminates and thermoelectric devices including the thermoelectric materials.

Additional aspects will be set forth in part in the description which follows and, in part, will be apparent from the description, or may be learned by practice of example embodiments.

According to example embodiments, a composite laminate includes graphene, and a thermoelectric inorganic material including a single crystal having a hexagonal crystal system.

According to example embodiments, a thermoelectric material includes the composite laminate.

According to example embodiments, a thermoelectric device includes a thermoelectric material including the composite laminate.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view illustrating a composite laminate according to example embodiments;

FIG. 2 is a schematic view illustrating a thermoelectric module according to example embodiments;

FIG. 3 is a schematic view illustrating thermoelectric cooling by the Peltier effect;

FIG. 4 is a schematic view illustrating thermoelectric power generation by the Seebeck effect;

FIG. 5A is the result of X-ray diffraction (XRD) analysis of a composite laminate obtained in Example 1;

FIG. 5B is the result of XRD analysis of Sb₂Te₃ nanoplates obtained in Reference Example 1;

FIG. 6 is the result of energy dispersive X-ray spectroscopy (EDX) analysis of the composite laminate obtained in Example 1;

FIG. 7A is the result of scanning electron microscope (SEM) analysis of the composite laminate obtained in Example 1;

FIG. 7B is the result of SEM analysis of the Sb₂Te₃ nanoplates obtained in Reference Example 1;

FIG. 8 is the result of high-resolution transmission electron microscope (HRTEM)/selected area electron diffraction (SAED) analysis of the composite laminate obtained in Example 1;

FIG. 9A illustrates a Raman spectrum of the composite laminate obtained in Example 1;

FIG. 9B illustrates an enlarged Raman spectrum of Sb₂Te₃ in FIG. 9A;

FIG. 10 is a schematic view illustrating a structure of a spark plasma sintering apparatus;

FIG. 11 is a schematic view illustrating an apparatus for measuring electrical conductivity of the composite laminate of Example 1;

FIG. 12 illustrates conductivities of bulk pellets prepared using a graphene-Sb₂Te₃ composite laminate prepared in Example 1, an expanded graphite (EG)-Sb₂Te₃ mixture prepared in Comparative Example 1, and Sb₂Te₃ nanoplates of Reference Example 1 according to Evaluation Example 6;

FIGS. 13 and 14 respectively illustrate Seebeck coefficients and power factors of bulk pellets prepared using the graphene-Sb₂Te₃ composite laminate prepared in Example 1, the EG-SB₂Te₃ mixture prepared in Comparative Example 1, and the Sb₂Te₃ nanoplates of Reference Example 1 according to Evaluation Example 7;

FIGS. 15 and 16 are SEM micrographs of bulk pellet A and bulk pellet B obtained according to Evaluation Example 8, respectively;

FIG. 17 is a graph showing Seebeck coefficients of the bulk pellet A and bulk pellet B obtained according to Evaluation Example 8; and

FIG. 18 is a graph showing conductivities of the bulk pellet A and bulk pellet B obtained according to Evaluation Example 8.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

As used herein, the term “and/or” includes any and all combinations of one or more of the associated listed items. Expressions such as “at least one of,” when preceding a list of elements, modify the entire list of elements and do not modify the individual elements of the list.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

A thermoelectric material according to example embodiments may include a laminate of graphene and a thermoelectric inorganic material. In the composite laminate of graphene and a thermoelectric inorganic, a crystal structure of the thermoelectric inorganic material may have a predetermined or given orientation. The thermoelectric inorganic material may be a single crystal having a hexagonal crystal system.

The thermoelectric inorganic material, for example, is particles having a length of a horizontal axis of the hexagonal crystal system ranging from about 0.01 μm to about 10 μm and a thickness ranging from about 1 nm to about 100 nm.

Any material may be used as the thermoelectric inorganic material without limitation so long as it may be used in the art, and may be, for example, at least one element selected from the group consisting of a transition metal, a rare earth element, a Group 13 element, a Group 14 element, a Group 15 element, and a Group 16 element.

Examples of the rare earth element may include Yttrium (Y), cerium (Ce), and lanthanum (La), and examples of the transition metal may include one or more of titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), cobalt (Co), nickel (Ni), copper (Cu), zinc (Zn), silver (Ag), and rhenium (Re).

One or more of boron (B), aluminum (Al), gallium (Ga), and indium (In) may be used as the Group 13 element, and one or more of carbon (C), silicon (Si), germanium (Ge), tin (Sn), and lead (Pb) may be used as the Group 14 element.

One of more of phosphorous (P), arsenic (As), antimony (Sb), and bismuth (Bi) may be used as the Group 15 element, and one or more of sulfur (S), selenium (Se), and tellurium (Te) may be used as the Group 16 element. For example, one or more thermoelectric inorganic materials, including two or more elements among the above elements, may be used.

Examples of the thermoelectric inorganic material, including such elements, may be Bi—Te-based, Bi—Se-based, Co—Sb-based, Pb—Te-based, Ge-terbium (Tb)-based, Si—Ge-based, Bi—Sb—Te-based, Sb—Te-based, samarium (Sm)—Co-based, and transition metal silicide-based thermoelectric inorganics. Electrical characteristics of the thermoelectric inorganics may be improved by including one or more elements selected from the group consisting of a transition metal, a rare earth element, a Group 13 element, a Group 14 element, a Group 15 element, and a Group 16 element as a dopant.

Examples of the Bi—Te-based thermoelectric inorganic material may be a Bi₂Te₃— or a (Bi,Sb)₂(Te,Se)₃-based thermoelectric inorganic material in which Sb and Se are used as dopants, and an example of the Bi—Se-based thermoelectric inorganic material may be Bi₂Se₃.

Examples of the Co—Sb-based thermoelectric inorganic material may be CoSb₃-based thermoelectric inorganics, examples of the Sb—Te-based thermoelectric inorganic material may be Sb₂Te₃, AgSbTe₂, and CuSbTe₂, and examples of the Pb—Te-based thermoelectric inorganic material may be PbTe and (PbTe)ₘAgSbTe₂ (m=1 or 2).

Examples of the thermoelectric inorganic material includes one or more selected from the group consisting of Bi₂Te₃, Sb₂Te₃, and Bi₂Se₃.

A crystal structure of the thermoelectric inorganic material is a hexagonal crystal system in which atoms are stacked perpendicular to a c-axis. A structure having five layers stacked therein is denoted as a quintuple layer and the hexagonal crystal system is composed of three quintuple layers. Atoms along an a-axis and a b-axis are covalently bonded, but a bonding surface between each quintuple layer is bonded with a relatively weak van der Waals force. As a result, the Bi₂Te₃-based thermoelectric inorganic material has relatively low mechanical strength and exhibits relatively high anisotropy of electrical transport phenomena.

For example, lattice constants, a and b, in the Bi₂Te₃, Sb₂Te₃, and Bi₂Se₃ compounds may be in a range of about 4.200 Å to about 4.300 Å, and for example, may be about 4.264 Å. For example, c may be in a range of about 29.000 Å to about 31.000 Å, and for example, may be about 30.458 Å.

The thermoelectric inorganic material has a thin film structure. A thickness of the thin film may be in a range of about 1 nm to about 100 nm.

That the thermoelectric inorganic material is a single crystal may be confirmed through high-resolution transmission electron microscope (HRTEM)/selected area electron diffraction (SAED) analysis. For example, it may be understood through SAED that the thermoelectric inorganic material is a desirably crystallized single crystal.

In the case that the thermoelectric inorganic material is Sb₂Te₃, a plane spacing obtained through the HRTEM analysis is in a range of about 0.19 nm to about 2.3 nm, and for example, is about 0.21 nm. This value corresponds to a (110) lattice plane of Sb₂Te₃.

In the case that the thermoelectric inorganic material is Sb₂Te₃, a Raman spectrum of the compound shows peaks at about 90±1 cm⁻¹, about 119.8±0.8 cm⁻¹, about 139.6±1 cm⁻¹, about 251.3±0.3 cm⁻¹, and about 450±1 cm⁻¹, and because the peaks are related to a Sb₂Te₃ thin film, it may be understood that the Sb₂Te₃ has a thin plate structure. For example, the peaks at about 119.8±0.8 cm⁻¹, about 251.3±0.3 cm⁻¹, and about 450±1 cm⁻¹ are related to semiconductor characteristics and an intensity ratio (Peak A/Peak B) of the peak (Peak A) observed at about 119.8±0.8 cm⁻¹ and the peak (Peak B) observed at about 251.3±0.3 cm⁻¹ is in a range of about 2.5 to about 2.9, and for example, is about 2.8.

The foregoing composite laminate of graphene and a thermoelectric inorganic material has a thin plate structure in which thermal conductivity may be decreased due to phonon scattering at an improved interface and charge mobility may also be increased due to a relatively large area, and thus, relatively high electrical conductivity may be obtained. Because the composite laminate has an improved thermoelectric performance, the composite laminate may be suitable for a thermoelectric device, a thermoelectric module, or a thermoelectric apparatus.

Graphene constituting the composite laminate is a material having relatively high conductivity and mobility, and in the case where the graphene is used in the thermoelectric inorganic material to form a laminate, the thermoelectric performance of the thermoelectric inorganic material may be improved due to the desirable electrical characteristics of the graphene.

Performance of a thermoelectric material is defined by using a ZT value of the following Equation 1, which is commonly referred as a dimensionless figure of merit:

ZT=(S²σT)/k <Equation 1>

where ZT is a figure of merit, S is a Seebeck coefficient, and a is electrical conductivity, T is absolute temperature, and k is thermal conductivity.

As shown in Equation 1, the Seebeck coefficient and electrical conductivity, e.g., a power factor (S²σ), may be increased and the thermal conductivity may be decreased in order to increase the ZT value of the thermoelectric material.

Graphene is a material having a honeycomb-shaped, two-dimensional plane structure in which carbons are connected to one another in the form of a hexagon, and has desirable electrical characteristics due to improved charge mobility. With respect to heat conduction characteristics, the movement of phonons may be blocked due to scattering in an out-of-plane direction of the graphene (direction perpendicular to the plane structure of the graphene) and thus, the heat conduction characteristics in the out-of-plane direction may be reduced in comparison to heat conduction characteristics in an in-plane direction (in the plane structure of the graphene). Therefore, in the case that such characteristics of the graphene in the in-plane or out-of-plane direction are used in a thermoelectric material, high electrical conductivity and low thermal conductivity may be achieved and thus, the performance of the thermoelectric material may be improved.

A thermoelectric material according to example embodiments includes a composite laminate of a thermoelectric inorganic material and graphene. The composite laminate may be obtained by forming a thermoelectric inorganic material, for example, a thermoelectric inorganic material having the form of a thin film, on graphene having a plane structure. A laminate having a multilayer structure may be formed by alternatingly stacking the graphene and the thermoelectric inorganic material.

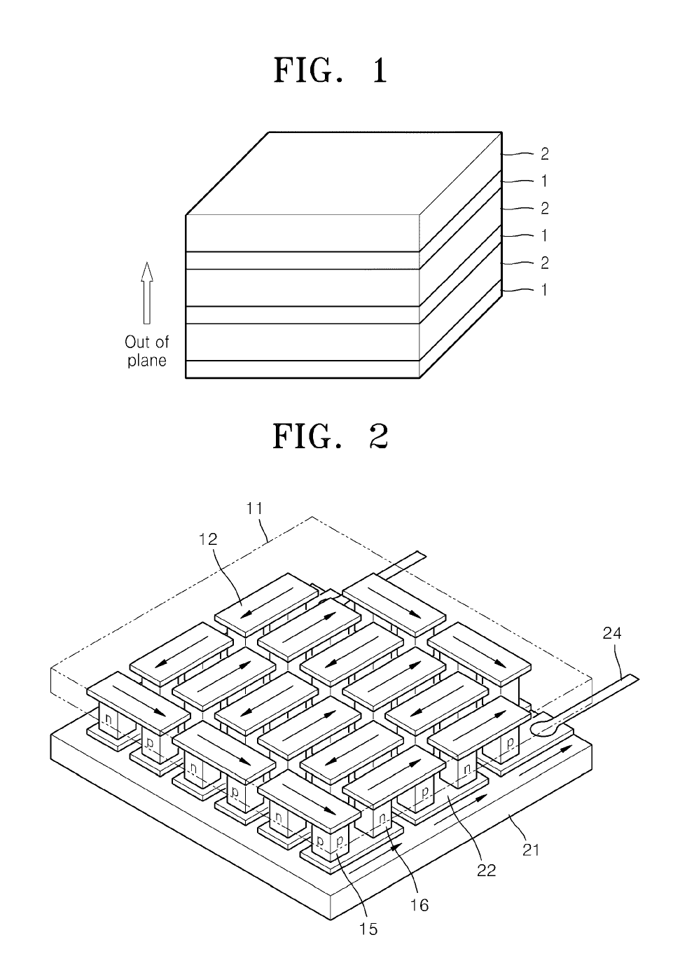

Referring to a laminate having a multilayer structure illustrated in FIG. 1, it may be understood that graphene 1 and a thermoelectric inorganic material 2 are repeatedly stacked three times. The stacking of the graphene 1 and the thermoelectric inorganic material 2, for example, may be repeated about 1 time to about 100 times.

The graphene used in the graphene-containing thermoelectric material is a material in which a plurality of carbon atoms are connected by covalent bonds to form polycyclic aromatic molecules. The carbon atoms connected by covalent bonds may form a six-membered ring as a basic repeating unit, but a five-membered ring and/or a seven-membered ring may be further included. As a result, the graphene may appear as a single layer of covalently bonded carbon atoms (typical sp² bond). The graphene may be formed of a single layer. However, a multilayer may be formed by stacking a plurality of single layers. For example, the number of layers may be in a range of about 1 to about 300, or about 2 to about 100, or about 3 to about 50. With respect to multilayer graphene, because the phonons are scattered due to the effect of an interlayer interface, improved thermoelectric performance may be obtained in the out-of-plane direction.

In the case where the graphene has multiple layers, the graphene may have various stack structures. For example, the stack structure may include an AB-stack or random-stack structure, in which the random-stack structure may have better characteristics than the AB-stack structure in terms of the blocking of the phonons in the out-of-plane direction, carrier mobility, and electrical conductivity.

The graphene is not particularly limited, and may be prepared by various preparation methods. For example, the graphene may be prepared by an exfoliation process or a growth process.

A graphene-containing thermoelectric material may be formed by stacking a thermoelectric inorganic material on the graphene obtained by the foregoing process.

Crystal orientation of a thermoelectric inorganic thin film formed on the graphene may be measured through X-ray diffraction (XRD) and the crystal orientation thereof may be (00) according to the measurement results of XRD (where l is an integer between 1 and 99).

Various physical properties in the out-of-plane direction illustrated in FIG. 1 may be improved due to the (00l) crystal orientation of the thermoelectric inorganic thin film. That is, because the thermoelectric inorganic thin film having a predetermined or given orientation is formed on the graphene, crystallinity and electronic structure at an interface between the graphene having metallic properties and the thermoelectric inorganic material having semiconductor properties are changed to increase the Seebeck coefficient and the transfer of charged particles may be accelerated, and thus, an increase in the electrical conductivity and charge mobility may be induced. Also, because phonon scattering at the interface between the graphene and the thermoelectric inorganic material is increased, control of the thermal conductivity may be possible. Furthermore, quantum confinement effects may be induced by forming the thermoelectric inorganic material in nanoscale, and the thermal conductivity may be decreased due to phonon confinement (phonon glass electron crystal (PGEC) concept) in the nano thin film.

Because the quantum confinement effects may increase the density of a state of carriers in the material to increase effective mass, an offset relationship between the electrical conductivity and the Seebeck coefficient is collapsed according to a concept of increasing the Seebeck coefficient while the electrical conductivity is not greatly changed. The PGEC concept is a concept in which only the thermal conductivity is decreased by blocking the movement of the phonons responsible for heat transfer and not interfering with the movement of the carriers.

As described above, the out-of-plane direction illustrated in FIG. 1 is a spatial concept that is distinguished from the in-plane direction of the graphene having a plane structure and denotes a direction (z-axis) perpendicular to a plane (x-axis and y-axis). A crystalline thermoelectric inorganic material may be stacked in the out-of-plane direction.

The composite laminate of graphene and a thermoelectric inorganic material may be obtained by stacking the thermoelectric organic thin film on the graphene and at this time, the laminate may have a superlattice structure. The superlattice structure denotes a structure formed by repeatedly stacking the graphene and the thermoelectric organic thin film in sequence.

The composite laminate of graphene and a thermoelectric inorganic material may be obtained by stacking the thermoelectric organic thin film on the graphene, and a composite laminate having a multilayer structure may be formed by repeating the stacking. That is, the thermoelectric organic thin film is formed on the graphene, and the graphene is then stacked again on the thermoelectric organic thin film. Thereafter, a process of forming the thermoelectric organic thin film thereon is repeated many times, and thus, a composite laminate including graphene/thermoelectric inorganic material as a single unit may be formed. The number of graphene/thermoelectric inorganic material units included, for example, may be in a range of about 1 to about 100.

In the composite laminate of graphene and a thermoelectric inorganic, a p-type or n-type material may be used as the thermoelectric inorganic, and the graphene may be doped with a p-dopant or an n-dopant.

A composite laminate of graphene and a thermoelectric inorganic, according to example embodiments, may be prepared by using the following method:

Graphene is formed on a substrate and a thermoelectric inorganic thin film is formed on the graphene to prepare a composite laminate of graphene and a thermoelectric inorganic.

The thermoelectric inorganic material is a single crystal having a hexagonal crystal system.

In the forming of the graphene on the substrate, graphene obtained by a growth process or an exfoliation process known in the art may be used, and for example, graphene having a single crystal or polycrystalline structure, or epitaxially grown graphene may be used without limitation. The number of layers of the graphene may be in a range of about 1 to about 300.

An example of the exfoliation process for preparing the graphene may include a method of separating graphene from a material internally containing a graphene structure, e.g., graphite or highly oriented pyrolytic graphite (HOPG), by using a mechanical device (e.g., Scotch tape) or an oxidation-reduction process.

Another example of the exfoliation process for preparing the graphene may include a method of preparing graphene in which expanded graphite is obtained by applying microwaves to a graphite intercalation compound (GIC) and a liquid phase exfoliation process for dispersing the expanded graphite in a solvent is selectively performed. The graphene obtained by using this method may have no defects and may not be oxidized, and thus, thermoelectric characteristics thereof may be desirable.

N-methyl pyrrolidone may be used as the solvent and ultrasonic waves may be used during the dispersion. The process of dispersing the graphene in the solvent may be performed for about 0.5 hours to about 30 hours.

The GIC is prepared by insertion of intercalants into graphite. Examples of the intercalant may be sulfuric acid, chromic acid, or a mixture thereof.

The microwaves have a power ranging from about 50 W to about 1,500 W and a frequency ranging from about 2.45 GHz to about 60 GHz. An application time of the microwaves may be changed according to the frequency and for example, the microwaves may be applied for about 10 minutes to about 30 minutes.

An example of the growth process for preparing the graphene may include a method of forming a graphene crystal structure by growing carbon adsorbed or included in an inorganic-based material, e.g., silicon carbide, on a surface of the inorganic-based material at a high temperature or by dissolving or adsorbing a gas-phase carbon source, e.g., methane and ethane, on a catalyst layer, e.g., nickel and copper thin films, at a high temperature and then crystallizing the carbon source on a surface of the catalyst layer through cooling. The graphene obtained by the above method may have a large area of about 1 cm² or more, the shape thereof may be uniformly prepared, and the number of layers may be freely adjusted by controlling the type and thickness of a substrate or catalyst, reaction time, reaction rate, and a concentration of reaction gas. As a result, the graphene obtained by using the growth process may have desirable reproducibility and mass production may be facilitated. Any growth process may be used without limitation so long as it is known in the art.

According to example embodiments, the graphene may be prepared by chemical vapor deposition. An inorganic substrate, including one or more of a Si substrate, a glass substrate, a GaN substrate, and a silica substrate; or a metal substrate, including one or more selected from the group consisting of Ni, Co, Fe, platinum (Pt), palladium (Pd), gold (Au), Al, Cr, Cu, Mn, Mo, rhodium (Rh), iridium (Ir), Ta, Ti, W, uranium (U), V, and Zr substrates, may be used as the substrate having the graphene formed thereon.

The graphene is formed on the substrate as described above, and a thermoelectric inorganic thin film is then formed on the graphene. The thermoelectric inorganic thin film may be formed by exfoliation of a thin film from a particulate thermoelectric inorganic material or by directly growing a thermoelectric inorganic thin film on the graphene.

As a growth process for preparing a thin film by growing the thermoelectric inorganic material on the graphene, the thermoelectric inorganic material may be stacked in nanoscale, e.g., in the form of a thin film, on the graphene through a method, e.g., deposition. The method of deposition is not particularly limited. However, a physical vapor deposition method, e.g., an evaporation method or sputtering, or a chemical vapor deposition method, e.g., a metal-organic chemical vapor deposition method or hydride vapor epitaxy, may be used.

Hereinafter, a method of preparing a composite laminate, according to example embodiments, will be described, in which a thermoelectric inorganic thin film is formed on graphene by using a microwave-solvothermal method.

Graphene is dispersed in a first solvent, and the first solvent is mixed with a first element (E1) salt to obtain a graphene-containing mixture.

Exfoliated graphene is used as the graphene.

A salt containing a Group 15 element is used as the E1 salt, and for example, chloride, sulfate, or nitrate including one or more of P, As, Sb, and Bi may be used.

For example, the E1 salt may include antimony chloride, antimony sulfate, antimony nitrate, bismuth chloride, bismuth nitrate, and bismuth sulfate.

A polyol is used as the first solvent dispersing the graphene, and 1,5-pentanediol, ethylene glycol, diethylene glycol, triethylene glycol, or tetraethylene glycol may be used as the polyol. An amount of the first solvent is in a range of about 100 parts by weight to about 5,000 parts by weight based on 100 parts by weight of the graphene. In the case that the content of the first solvent is within the above range, the graphene may be uniformly dispersed.

The dispersion may be more smoothly performed by using ultrasonic waves during the mixing of the graphene with the E1 salt.

The sonication is performed under conditions of a frequency ranging from about 2.45 KHz to about 60 KHz and a power ranging from about 50 W to about 1,500 W.

Separately, a second element (E2) complex precursor, an electron donating element-containing organic compound, and a second solvent are mixed, and microwaves are applied thereto to form an E2 complex. Thus, an E2 complex-containing mixture is obtained.

One or more selected from the group consisting of tri-n-octylphosphine, trioctylamine, octylamine, hexadecylamine, dimethyloctylamine, trioctylphosphine oxide, trioctylphosphine, oleic acid, and bis(2-ethylhexyl)hydrogen phosphate may be used as the electron donating element-containing organic compound. An amount of the electron donating element-containing organic compound is in a range of about 100 parts by weight to about 500 parts by weight based on 100 parts by weight of the E2 complex precursor.

Tri-n-octylphosphine is used as the second solvent. An amount of the second solvent is in a range of about 100 parts by weight to about 5,000 parts by weight based on 100 parts by weight of the E2 salt.

The E2 complex precursor includes a Group 16 element or a compound containing the Group 16 element, and for example, one or more of S, Se, and Te may be used. For example, Te powder is used in example embodiments.

The microwaves may be applied at a power ranging from about 50 W to about 1,500 W and a frequency ranging from about 1 Hz to about 2.45 GHz. An application time of the microwaves may be changed according to the power and frequency of the microwaves, and for example, the microwaves may be applied for about 30 seconds to about 60 minutes.

When the microwaves are applied, a reaction temperature of the mixture for forming the E2 complex may be in a range of about 200° C. to about 250° C.

Examples of the E2 complex may be Te-trioctylphosphine (TOP) complex and Te-trioctylphosphine oxide (TOPO).

The graphene-containing mixture and the E2 complex-containing mixture are mixed with each other and an antioxidant is added thereto.

The antioxidant may prevent or inhibit oxidation of the composite laminate and simultaneously, may induce particles of the E2 to be formed in a targeted shape by assisting a reduction.

Examples of the antioxidant may be thioglycolic acid.

An amount of the antioxidant used is in a range of about 1 mole to about 100 moles based on 1 mole of the E2 complex. In the case that the content of the antioxidant is within the above range, the shape of the final composite laminate may be obtained as desired. A composite laminate may be obtained after the application of the microwaves to the mixture.

Thereafter, the product is cleaned with a solvent, e.g., acetone, and dried. The drying is performed at a temperature ranging from about 150° C. to about 250° C.

Microwaves applied to a mixture including the graphene-containing mixture and the E2 complex-containing mixture have a frequency ranging from about 2.45 GHz to about 60 GHz and a power ranging from about 50 W to about 1,500 W.

According to example embodiments, the E2 complex is Te-TOP and the E1 salt is antimony chloride. When such E2 complex and E1 salt are used, a complex laminate containing a graphene/Sb₂Te₃ composite having graphene and a single crystal thermoelectric inorganic material with a hexagonal crystal system may be obtained.

In the above preparation method, a method of preparing a composite laminate is described, in which a thermoelectric inorganic thin film is formed on graphene by using a microwave-solvothermal method. However, a microwave-hydrothermal method may be used instead of the microwave-solvothermal method known in the art.

According to the foregoing preparation method using a microwave-solvothermal or microwave-hydrothermal reaction, preparation of the composite laminate containing a thermoelectric inorganic material on the graphene may be facilitated, mass production in a short reaction time may be possible, and manufacturing costs may be relatively low.

Because the microwave-solvothermal or microwave-hydrothermal reaction is a reaction performed at a constant temperature and pressure, evaporation of the solution may be prevented or inhibited and reproduction of uniform shape and size may be possible.

The thermoelectric inorganic material may have the form of a single crystal structure. Also, the thermoelectric inorganic material may have p-type semiconductor properties or n-type semiconductor properties.

With respect to the graphene/thermoelectric inorganic composite laminate obtained through the foregoing process, because the thermoelectric inorganic thin film having a predetermined or given orientation is formed on the graphene, the crystallinity and electronic structure at the interface between the graphene having metallic properties and the thermoelectric inorganic material having semiconductor properties are changed to increase the Seebeck coefficient and the transfer of charged particles may be accelerated, and thus, an increase in the electrical conductivity and charge mobility may be induced. Also, because the phonon scattering at the interface between the graphene and the thermoelectric inorganic material is increased, the control of the thermal conductivity may be possible. Furthermore, the quantum confinement effects may be induced by forming the thermoelectric inorganic material in nanoscale, and the thermal conductivity may be decreased due to the PGEC concept in the nano thin film.

The graphene/thermoelectric inorganic composite laminate having an improved thermoelectric performance may be suitable for a thermoelectric material. Therefore, a thermoelectric device may be fabricated by forming a thermoelectric material containing the graphene/thermoelectric inorganic composite laminate by using a method, e.g., cutting. The thermoelectric device may be a p-type thermoelectric device. The thermoelectric device denotes that the thermoelectric material is formed in a predetermined or given shape, for example, a rectangular shape.

In addition, the thermoelectric device may exhibit a cooling effect by being combined with electrodes and the application of current, and may exhibit a power generation effect by a temperature difference across the thermoelectric device.

FIG. 2 illustrates an example of a thermoelectric module including the thermoelectric device. As illustrated in FIG. 2, top electrodes 12 (first electrodes) and bottom electrodes 22 (second electrodes) are respectively formed in patterns on a top insulating substrate 11 and a bottom insulating substrate 21, and the top electrodes 12 and the bottom electrodes 22 are in contact with p-type thermoelectric components 15 and n-type thermoelectric components 16. The top and bottom electrodes 12 and 22 are connected to the outside of the thermoelectric device by lead electrodes 24. The foregoing thermoelectric device may be used as the p-type thermoelectric component 15. Any n-type thermoelectric component known in the art may be used as the n-type thermoelectric component 16 without limitation.

Gallium arsenide (GaAs), sapphire, silicon, Pyrex, and quartz substrates may be used as the top and bottom insulating substrates 11 and 21. A material of the top and bottom electrodes 12 and 22 may be variously selected from copper, aluminum, nickel, gold, and titanium, and the size thereof may also be variously selected. Any patterning method known in the art may be used as a method of patterning to form the top and bottom electrodes 12 and 22 without limitation, and for example, a lift-off semiconductor process, a deposition method, and a photolithography method may be used.

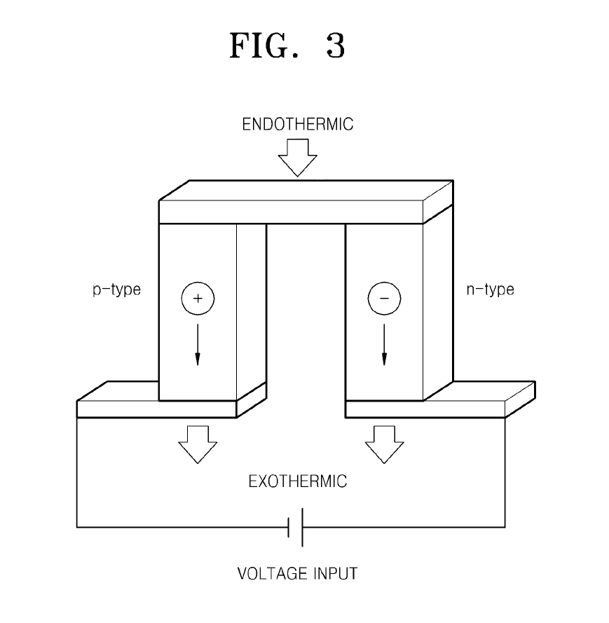

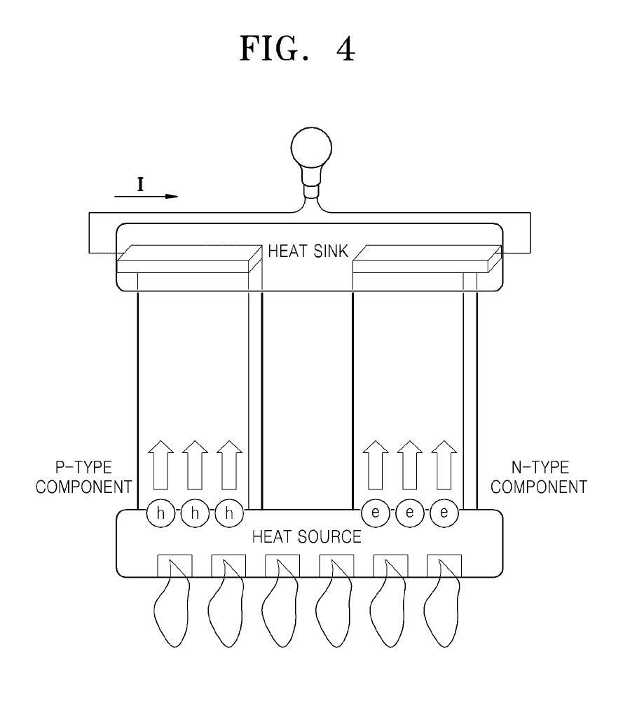

In a thermoelectric module according to example embodiments, one of the first electrode and the second electrode may be exposed to a heat source as illustrated in FIGS. 3 and 4. In a thermoelectric device according to example embodiments, one of the first electrode and the second electrode may be electrically connected to a power source or may be electrically connected to the outside of the thermoelectric module, for example, an electric device (e.g., battery) consuming or storing power.

In the thermoelectric module according to example embodiments, one of the first electrode and the second electrode may be electrically connected to a power source.

Hereinafter, example embodiments will be described in more detail, according to the following examples. However, example embodiments are not limited thereto.

### Preparation Example 1

### Preparation of Exfoliated Graphene

Microwaves (power: 700 W, frequency: 2.45 GHz) were applied to about 4 mg of a graphite intercalation compound (GIC) (Hyundai Coma, HCE-995270) for about 1 minute to prepare expanded graphite (EG).

### Example 1

### Preparation of Graphene-Sb₂Te₃ Composite Laminate

About 1 g of tellurium (Te) powder and about 10 ml of tri-n-octylphosphine (TOP) were put in a Teflon-lined stainless steel autoclave container and treated at about 220° C. for about 2 minutes in a microwave-assisted solvothermal apparatus (MARS5, microwave power: 1,200 W, frequency: 2.45 GHz) to prepare a yellow Te-TOP solution.

About 0.1 g of EG obtained in Preparation Example 1 and about 25 ml of 1.5-pentanediol (Pent) were treated by tip sonication (ultrasonic frequency 20 KHz, power 540 W) for about 30 minutes and about 1 g of SbCl₃ was then mixed therewith to prepare a mixture. The mixture was mixed by bath sonication (ultrasonic frequency 40 KHz, power 400 W) for about 15 minutes to prepare a transparent EG-SbCl₃-Pent solution.

About 10 mg of the Te-TOP solution, the EG-SbCl₃-Pent solution, and about 500 μl of thioglycolic acid (TGA) were put in a Teflon-lined stainless steel autoclave container, and the container was put in a microwave-assisted solvothermal apparatus (MARS5, CEM corporation) (microwave power: 1,200 W, frequency: 2.45 GHz) and treated at about 220° C. for about 30 seconds. Powder thus obtained was cleaned with acetone and the cleaned powder was then dried at about 200° C. for about 5 hours in a vacuum oven to obtain a graphene-Sb₂Te₃ composite laminate in the form of powder.

In the composite laminate, Sb₂Te₃ has a hexagonal crystal system, in which a length of a horizontal axis of the hexagonal crystal system was about 1.6 μm and a thickness thereof was about 35 nm.

### Example 2

### Preparation of Graphene-Sb₂Te₃ Composite Laminate

About 1 g of Te powder and about 10 ml of TOP were put in a Teflon-lined stainless steel autoclave container and treated at about 220° C. for about 2 minutes in a microwave-assisted solvothermal apparatus (MARS5, microwave power: 1,200 W, frequency: 2.45 GHz) to prepare a yellow Te-TOP solution.

About 25 ml of 1.5-pentanediol and about 1 g of antimony trichloride (SbCl₃) were mixed and treated by bath sonication (ultrasonic frequency 40 KHz, power 400 W) for about 15 minutes to prepare a transparent SbCl₃-pentanediol solution.

Separately, graphene (1 layer to a few layers) having a size of about 0.8 cm×about 0.8 cm, which was obtained through atmospheric pressure chemical vapor deposition (CVD), was transferred onto an oxidized high-resistance p-doped Si wafer with a 500 nm SiO₂ layer having a size of about 1 cm×about 1 cm.

The graphene having a size of about 0.8 cm×about 0.8 cm on the oxidized high-resistance p-doped Si wafer with a SiO₂ layer, the Te-TOP solution, and about 500 μl of TGA were put in a Teflon-lined stainless steel autoclave container and treated at about 220° C. for about 30 minutes in a microwave-assisted solvothermal apparatus (MARS5, microwave power: 1,200 W, frequency: 2.45 GHz) to obtain a graphene-Sb₂Te₃ composite laminate in the form of powder.

In the composite laminate, Sb₂Te₃ has a hexagonal crystal system, in which a length of a horizontal axis of the hexagonal crystal system was about 1.6 μm and a thickness thereof was about 35 nm.

### Reference Example 1

### Preparation of Sb₂Te₃ Nanoplates

About 1 g of Te powder and about 10 ml of TOP were put in a Teflon-lined stainless steel autoclave container and treated at about 220° C. for about 2 minutes in a microwave-assisted solvothermal apparatus (MARS5, microwave power: 1,200 W, frequency: 2.45 GHz) to prepare a yellow Te-TOP solution.

About 25 ml of 1.5-pentanediol and about 1 g of SbCl₃ were mixed and treated by bath sonication (ultrasonic frequency 40 KHz, power 400 W) for about 15 minutes to prepare a transparent SbCl₃-pentanediol solution.

About 10 mg of the Te-TOP solution, the SbCl₃-pentanediol solution, and about 500 μl of TGA were put in a Teflon-lined stainless steel autoclave container, and the container was put in a microwave-assisted solvothermal apparatus (MARS5, CEM corporation) (microwave power: 1,200 W, frequency: 2.45 GHz) and treated at about 220° C. for about 30 seconds. Powder thus obtained was cleaned with acetone and the cleaned powder was then dried at about 200° C. for about 5 hours in a vacuum oven to obtain Sb₂Te₃ nanoplates.

### Comparative Example 1

### Preparation of EG-Sb₂Te₃ Mixture

An EG-Sb₂Te₃ mixture was prepared by mixing about 0.1 g of the EG obtained in Preparation Example 1 and about 1 g of the Sb₂Te₃ obtained in Reference Example 1 in a mortar.

### Evaluation Example 1

### XRD Measurements

A 12 KW X-ray machine by Bruker AXS GmbH was used during the following XRD analysis, and the XRD analysis was performed under measurement conditions of a scanning angle ranging from about 5 degrees to about 80 degrees and a scanning speed of about 4 degrees/min.

1) Composite Laminate Obtained in Example 1

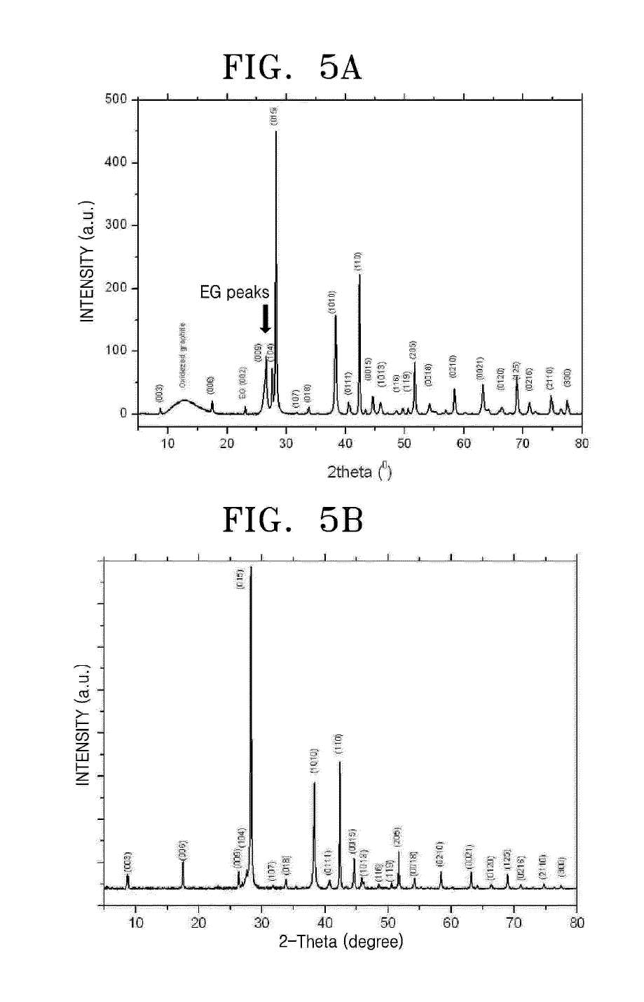

XRD analysis was performed on the composite laminate obtained in Example 1 and the results thereof are presented in FIG. 5A.

Referring to FIG. 5A, it was confirmed that the composite laminate had (006), (009), (0015), and (0018) crystal planes and it may be understood that the composite laminate had a predetermined or given orientation in the out-of-plane direction (direction perpendicular to the laminate). In FIG. 5A, an EG peak, which was a graphene peak, was observed.

2) Sb₂Te₃ Nanoplates of Reference Example 1

XRD analysis was performed on the Sb₂Te₃ nanoplates obtained in Reference Example 1 and the results thereof are presented in FIG. 5B.

### Evaluation Example 2

### EDX Analysis

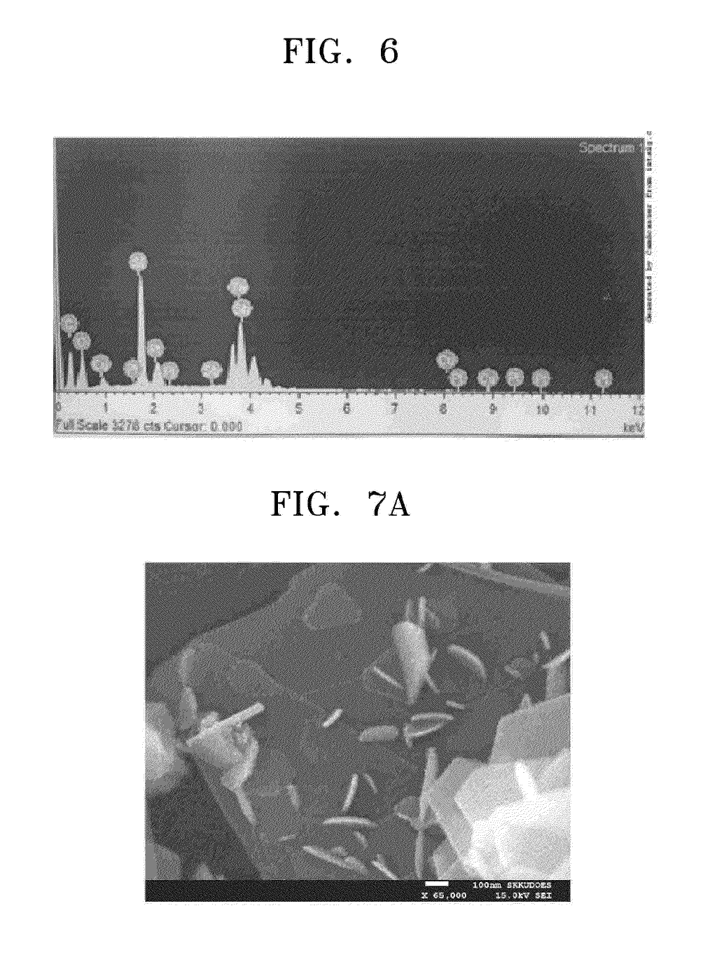

EDX analysis was performed on the composite laminate obtained in Example 1 and the results thereof are presented in FIG. 6 and Table 1 below.

The EDX analysis was performed using a JSM-7600F instrument by JEOL Ltd.

TABLE 1

| Category | Wt % | At % |
|---|---|---|
| C | 12.99 | 44.45 |
| O | 6.42 | 16.50 |
| Si | 11.22 | 16.42 |
| Cu | 2.60 | 1.68 |
| Sb | 23.28 | 7.86 |
| Te | 35.14 | 11.32 |
| Pt | 8.35 | 1.76 |

Referring to Table 1 and FIG. 6, a composition of the composite laminate obtained in Example 1 may be obtained.

### Evaluation Example 3

### SEM Analysis

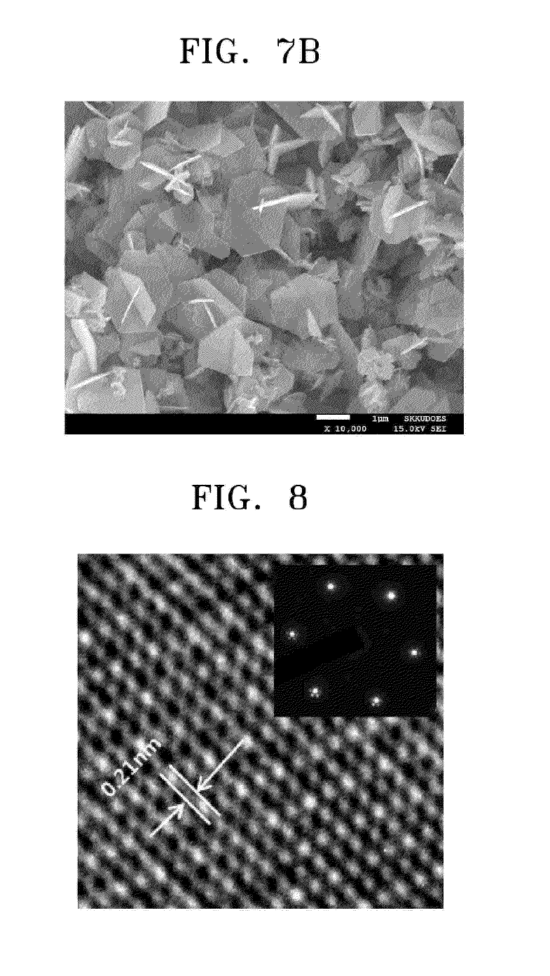

SEM analysis was performed on the composite laminate obtained in Example 1 and the Sb₂Te₃ nanoplates obtained in Reference Example 1, and the results thereof are respectively presented in FIGS. 7A and 7B. The SEM analysis was performed using a JSM-7600F instrument by JEOL Ltd.

Referring to FIGS. 7A and 7B, it may be understood that the composite laminate obtained in Example 1 had hexagonal Sb₂Te₃ nanoplates formed on the graphene, different from the case of Reference Example 1.

### Evaluation Example 4

### HRTEM/SAED Analysis

HRTEM/SAED analysis was performed on the composite laminate obtained in Example 1 and the results thereof are presented in FIG. 8. The HRTEM/SAED analysis was performed using HRTEM (800 KV) by JEOL Ltd.

Referring to FIG. 8, in the composite laminate obtained in Example 1, a plane spacing of about 0.21 nm corresponded to a (110) lattice plane of Sb₂Te₃. Referring to SAED (inset), it may be understood that the nanoplate was a well-crystallized single crystal.

### Evaluation Example 5

### Raman Spectrum Analysis

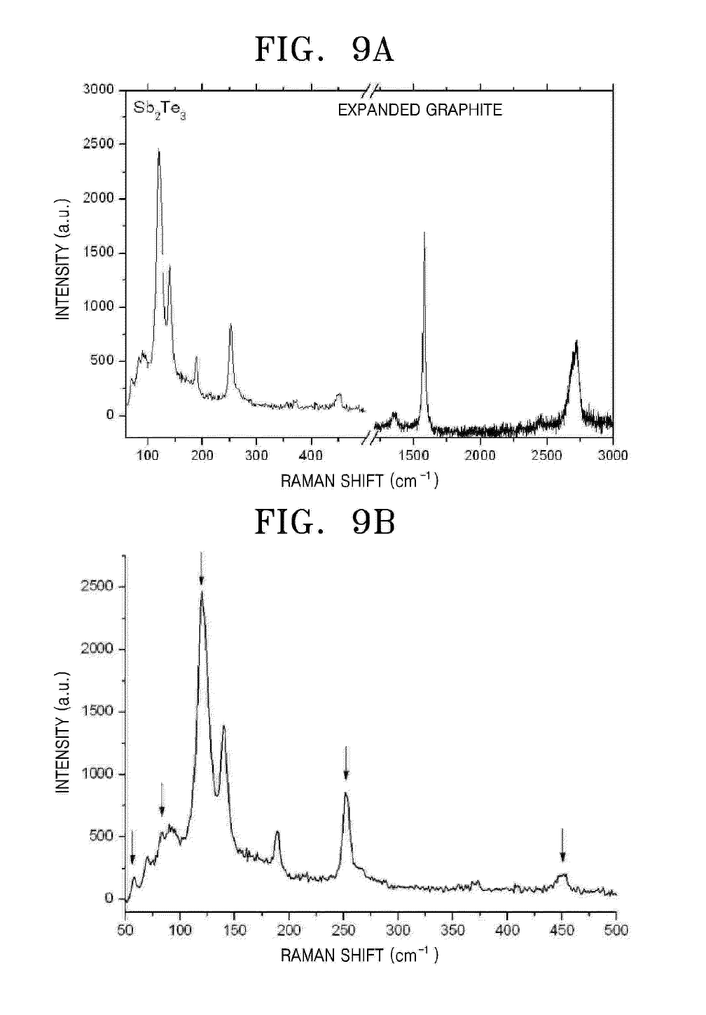

Raman analysis was performed on the composite laminate obtained in Example 1 and the results thereof are presented in FIGS. 9A and 9B.

The Raman analysis was performed using an RM-1000 Invia instrument (514 nm, Ar⁺ ion laser) by Renishaw plc.

Referring to FIG. 9A, the composite laminate obtained in Example 1 exhibited peaks at about 119 cm⁻¹, about 251 cm⁻¹, and about 450 cm⁻¹, and an intensity ratio of the peak at 119 cm⁻¹/the peak at 251 cm⁻¹ was about 2.8. It may be understood from the above peak information that Sb₂Te₃ was a single crystal.

Also, peaks appeared at about 1350 cm⁻¹, about 1580 cm⁻¹, and about 2700 cm⁻¹, and the peaks provided information about thickness, crystallinity, and the state of charge doping of graphene. The peak observed at about 1580 cm⁻¹ was a peak named “G-mode”, which may be caused by a vibration mode corresponding to stretching of a carbon-carbon bond, and energy of the G-mode may be determined by the density of surplus charges doped in the graphene.

The peak observed at about 1350 cm⁻¹ was a peak named “D-mode”, which may appear when defects existed in a SP² crystal structure.

The D/G intensity ratio provided information on the disorder of graphene crystals and was about 0.00198 in FIG. 9A.

The peak observed at about 2700 cm⁻¹ was a peak named “2D-mode”, which may be useful for evaluating the thickness of the graphene. It may be understood from data of FIG. 9A that the thickness of the graphene corresponded to a single layer.

FIG. 9B illustrates an enlarged Raman spectrum of Sb₂Te₃ extracted from the Raman spectrum of the composite laminate in FIG. 9A;

As illustrated in FIG. 9A, an intensity ratio of the peak at 119 cm⁻¹/the peak at 251 cm⁻¹ was about 2.8.

### Evaluation Example 6

### Electrical Conductivity Measurement (In-Plane Direction)

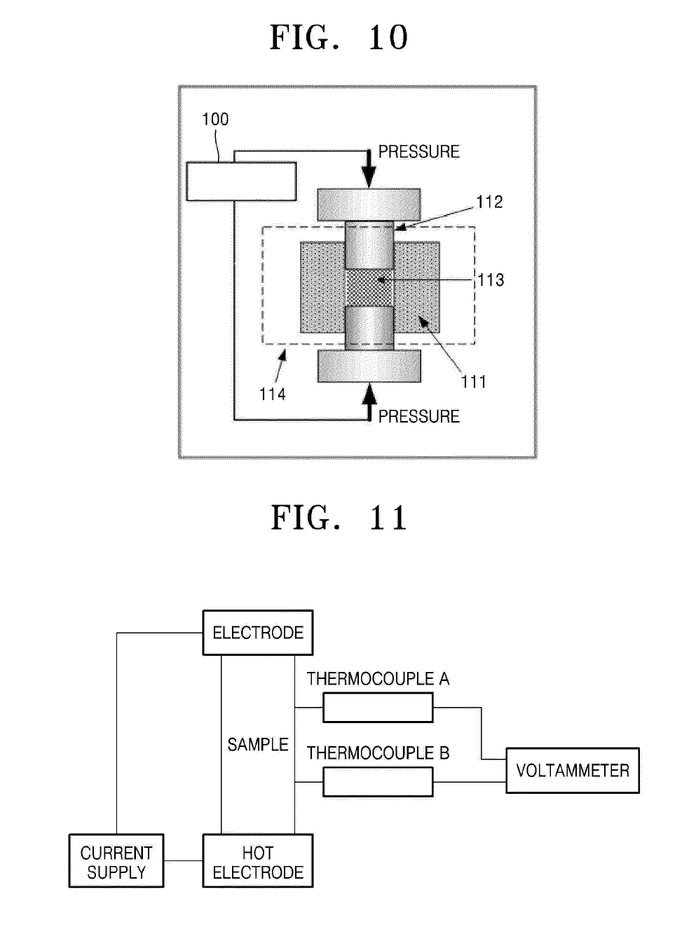

The graphene-Sb₂Te₃ composite laminate prepared in Example 1, the EG-Sb₂Te₃ mixture prepared in Comparative Example 1, and the Sb₂Te₃ nanoplates of Reference Example 1 were respectively ground in a mortar to prepare samples. Bulk pellets were prepared from each sample by pressure sintering at a temperature of about 390° C. and a pressure of about 70 MPa using a spark plasma sintering (SPS) apparatus in FIG. 10. The preparation of the bulk pellets using the SPS apparatus is described in detail below.

Direct pulse current supplied from a power supply 100 was applied to top and bottom punch electrodes 112 of a graphite pressure die 111 in a vacuum chamber 114. Then, the initiation of heating caused by spark discharges between composite powder 113 as well as the aid of spark discharge pressure promoted the transfer of a material and thus, bulk pellets, which are dense compacts, may be obtained.

Optimization of the SPS process conditions and the thermoelectric performance of the graphene-thermoelectric inorganic composites were evaluated.

Electrical conductivities of the composites obtained in Example 1 and Comparative Example 1 were measured. Electrical conductivity of Sb₂Te₃ was also presented for comparison with those of the composites obtained in Example 1 and Comparative Example 1.

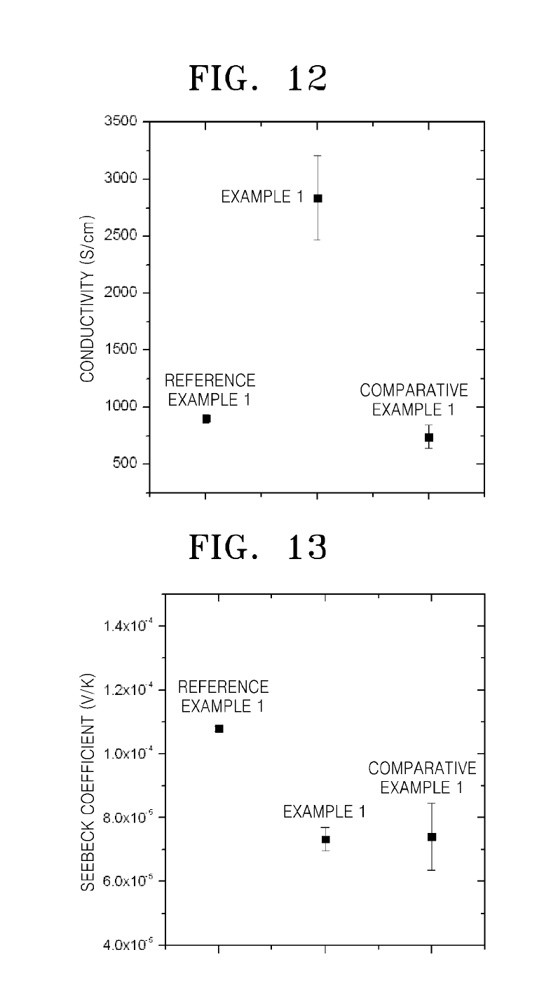

The results thereof are presented in FIG. 12. As illustrated in FIG. 12, with respect to the graphene/thermoelectric inorganic composite obtained in Example 1, it may be understood that the electrical conductivity thereof was increased in comparison to the cases of Comparative Example 1 and Reference Example 1.

Electrical conductivity was measured by a direct current (DC) 4-terminal method using a conductivity measurement apparatus in FIG. 11.

Thermocouples A and B in FIG. 11 were used as current probes and electrodes were used as voltage probes. Resistances were calculated from voltage drops between the voltage probes while different amounts of current were applied to the electrode and hot electrode. Electrical conductivity was calculated by being corrected with a shape factor calculated from an electrode area and a distance between the voltage probes.

### Evaluation Example 7

### Seebeck Coefficient Measurement (In-Plane Direction)

Seebeck coefficients of the graphene-Sb₂Te₃ composite laminate prepared in Example 1, the EG-Sb₂Te₃ mixture prepared in Comparative Example 1, and the Sb₂Te₃ nanoplates of Reference Example 1 were respectively measured by using the conductivity measurement apparatus illustrated in FIG. 11.

A temperature difference was applied to each sample through the hot electrode, a voltage difference and a temperature difference generated between both ends of each sample were measured with a voltammeter and the thermocouples A and B after the temperature distribution of each sample had reached a stable state, and thus, a value of the Seebeck coefficient for each sample was obtained from a ratio of the generated voltage to the temperature difference.

The Seebeck coefficient obtained from a slope of a ΔT-ΔV straight line was a measured value including Seebeck coefficients of the sample and the thermocouples. Therefore, in order to obtain the Seebeck coefficient of the sample, the measured value was corrected with the Seebeck coefficient of the thermocouples.

Electrical resistivity and the Seebeck coefficient of each bulk pellet according to a temperature were respectively measured by using a ZEM-3 (Ulvac-Rico) instrument as the conductivity measurement apparatus illustrated in FIG. 11.

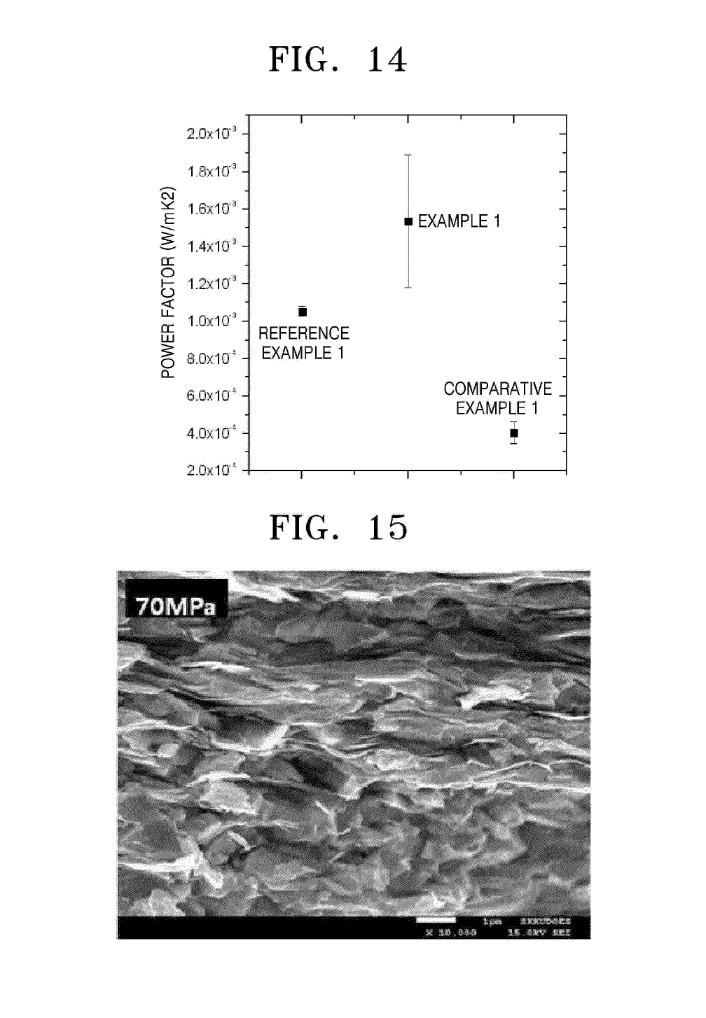

With respect to the above measurement method, the Seebeck coefficient in an in-plane (basal plane) direction was completely measured. The results thereof are presented in FIG. 13. Power factors were calculated using the measured values of conductivity and the results thereof are presented in FIG. 14.

As illustrated in FIGS. 12 and 14, with respect to the graphene/thermoelectric inorganic composite laminate obtained in Example 1, it may be understood that the electrical conductivity and power factor thereof were increased in comparison to the cases of Comparative Example 1 and Reference Example 1. Therefore, it may be understood that desirable thermoelectric performance was obtained.

### Evaluation Example 8

### SEM Analysis According to Sintering Pressure of SPS, and Conductivity and Seebeck Coefficient Measurements

In the case of preparing bulk pellets using the graphene/thermoelectric inorganic composite laminate of Example 1 according to Evaluation Example 6, two different SPS pressures of about 70 MPa and about 80 MPa were used to obtain bulk pellet A and bulk pellet B.

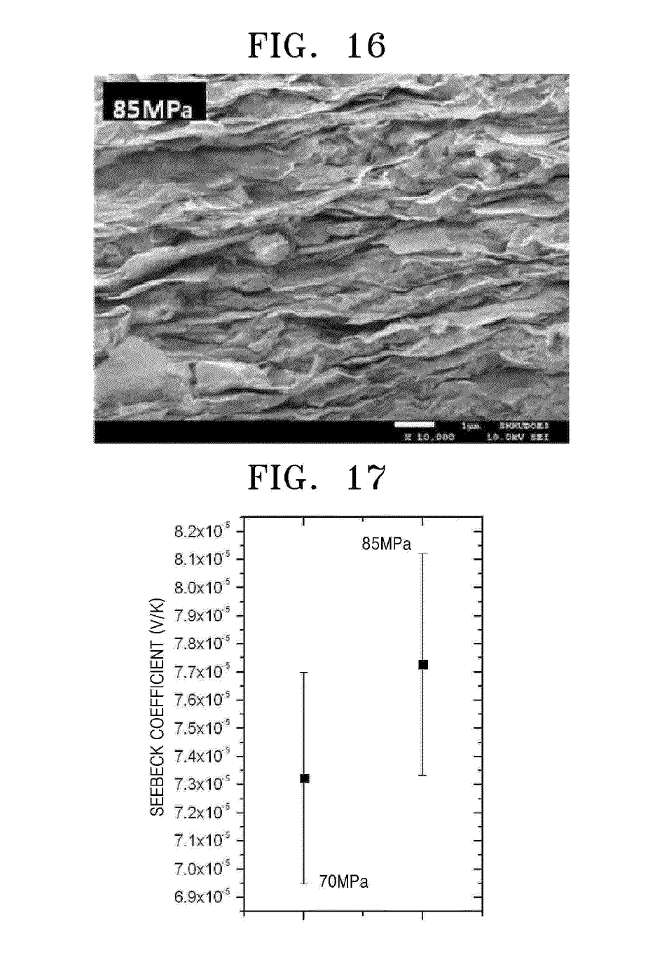

SEM analysis on bulk pellet A and bulk pellet B was performed and the results thereof are respectively presented in FIGS. 15 and 16.

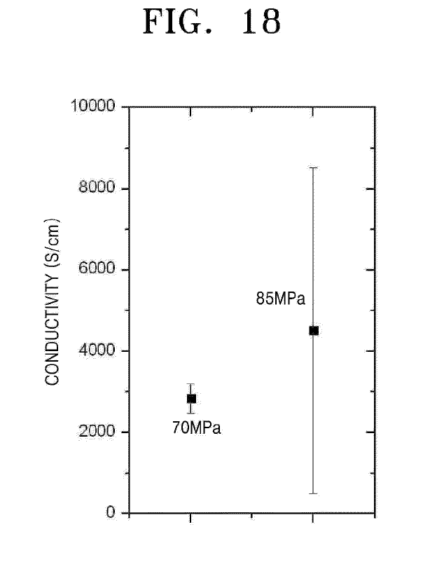

Conductivities and Seebeck coefficients of bulk pellet A and bulk pellet B were respectively measured according to the methods described in Evaluation Examples 6 and 7, and the results thereof are respectively presented in FIGS. 17 and 18.

Referring to FIGS. 15 to 18, when the bulk pellet was prepared by increasing sintering pressure of the SPS process, pores between particles of the bulk pellet were decreased, and thus, the bulk pellet became denser and relative density increased. Therefore, it may be understood that the electrical conductivity and Seebeck coefficient were increased.

A composite laminate including a thermoelectric inorganic material on graphene, according to example embodiments, may not only be more easily prepared and mass produced in a relatively short reaction time, but manufacturing costs may also be relatively low. A thermoelectric material, including the foregoing composite laminate, according to example embodiments, may exhibit an improved thermoelectric conversion efficiency due to an increase in electrical conductivity. Thermoelectric devices, thermoelectric modules, and thermoelectric apparatuses including the thermoelectric material may be suitable for general-purpose cooling appliances e.g., a non-refrigerant refrigerator and an air conditioner, waste heat power generation, thermoelectric nuclear power generation for military/aerospace applications, and a micro cooling system.

While the inventive concepts have been particularly shown and described with reference to example embodiments thereof, it will be understood by those of ordinary skill in the art that various changes in form and details may be made therein without departing from the spirit and scope of the inventive concepts as defined by the following claims.

What is claimed is:

1. A composite laminate comprising:
graphene; and
a thermoelectric inorganic material including a single crystal having a hexagonal crystal system.

2. The composite laminate of claim 1, wherein the thermoelectric inorganic material includes particles having a length ranging from about 0.01 μm to about 10 μm on a horizontal axis of the hexagonal crystal system and a thickness ranging from about 1 nm to about 100 nm.

3. The composite laminate of claim 1, wherein the graphene includes a layered structure with about 2 layers to about 100 layers.

4. The composite laminate of claim 1, wherein the graphene is obtained by an exfoliation process including applying microwaves to a graphite intercalation compound (GIC) to obtain expanded graphite and dispersing the expanded graphite in a solvent.

5. The composite laminate of claim 1, wherein the thermoelectric inorganic material includes a thin film structure having a thickness in a range of about 1 nm to about 100 nm.

6. The composite laminate of claim 1, wherein the thermoelectric inorganic material is at least one of bismuth (Bi)-tellurium (Te)-based, Bi-selenium (Se)-based, cobalt (Co)-antimony (Sb)-based, lead (Pb)—Te-based, germanium (Ge)-terbium (Tb)-based, silicon (Si)—Ge-based, Bi—Sb—Te-based, Sb—Te-based, and samarium (Sm)—Co-based compounds.

7. The composite laminate of claim 1, wherein the thermoelectric inorganic material is at least one of Sb₂Te₃, Bi₂Te₃, and Bi₂Se₃.

8. The composite laminate of claim 1, wherein:
the thermoelectric inorganic material is Sb₂Te₃, and
an intensity ratio (Peak A/Peak B) of a peak (Peak A) observed at about 119.8±0.8 cm⁻¹ and a peak (Peak B) observed at about 251.3±0.3 cm⁻¹ in a Raman spectrum is in a range of about 2.5 to about 2.9.

9. The composite laminate of claim 1, wherein the composite laminate is obtained by a method of preparing a composite laminate, the method comprising:
obtaining a graphene-containing mixture including,
dispersing graphene in a first solvent, and
mixing the first solvent with a first element (E1) salt;
obtaining a second element (E2) complex-containing mixture including,
mixing an E2 complex precursor, an electron donating element-containing inorganic compound, and a second solvent, and
applying microwaves to the E2 complex-containing mixture; and
mixing the graphene-containing mixture and the E2 complex-containing mixture;
adding an antioxidant to the graphene-containing mixture and the E2 complex-containing mixture; and
applying microwaves to the graphene-containing mixture and the E2 complex-containing mixture.

10. A thermoelectric material comprising a composite laminate, the composite laminate including,
graphene; and
a thermoelectric inorganic material including a single crystal having a hexagonal crystal system.

11. The thermoelectric material of claim 10, wherein the graphene is obtained by an exfoliation process including applying microwaves to a graphite intercalation compound (GIC) to obtain expanded graphite and dispersing the expanded graphite in a solvent.

12. The thermoelectric material of claim 10, wherein the thermoelectric inorganic material is at least one of bismuth (Bi)-tellurium (Te)-based, Bi-selenium (Se)-based, cobalt (Co)-antimony (Sb)-based, lead (Pb)—Te-based, germanium (Ge)-terbium (Tb)-based, silicon (Si)—Ge-based, Bi—Sb—Te-based, Sb—Te-based, and samarium (Sm)—Co-based compounds.

13. The thermoelectric material of claim 10, wherein the thermoelectric inorganic material is at least one of Sb₂Te₃, Bi₂Te₃, and Bi₂Se₃.

14. The thermoelectric material of claim 10, wherein:
the thermoelectric inorganic material is Sb₂Te₃, and
an intensity ratio (Peak A/Peak B) of a peak (Peak A) observed at about 119.8±0.8 cm⁻¹ and a peak (Peak B) observed at about 251.3±0.3 cm⁻¹ in a Raman spectrum is in a range of about 2.5 to about 2.9.

15. A thermoelectric device comprising a thermoelectric material including a composite laminate, the composite laminate including,
graphene; and
a thermoelectric inorganic material including a single crystal having a hexagonal crystal system.

16. The thermoelectric device of claim 15, wherein the graphene is obtained by an exfoliation process including applying microwaves to a graphite intercalation compound (GIC) to obtain expanded graphite and dispersing the expanded graphite in a solvent.

17. The thermoelectric device of claim 15, wherein the thermoelectric inorganic material is at least one of bismuth (Bi)-tellurium (Te)-based, Bi-selenium (Se)-based, cobalt (Co)-antimony (Sb)-based, lead (Pb)—Te-based, germanium (Ge)-terbium (Tb)-based, silicon (Si)—Ge-based, Bi—Sb—Te-based, Sb—Te-based, and samarium (Sm)—Co-based compounds.

18. The thermoelectric device of claim 15, wherein the thermoelectric inorganic material is at least one of Sb₂Te₃, Bi₂Te₃, and Bi₂Se₃.

19. The thermoelectric device of claim 15, wherein:
the thermoelectric inorganic material is Sb₂Te₃, and
an intensity ratio (Peak A/Peak B) of a peak (Peak A) observed at about 119.8±0.8 cm⁻¹ and a peak (Peak B) observed at about 251.3±0.3 cm⁻¹ in a Raman spectrum is in a range of about 2.5 to about 2.9.
